(19) United States
(12) Patent Application Publication
(10) Pub. No.: US 2009/0039907 A1
(43) Pub. Date: Feb. 12, 2009

(54) PROBE CARD FOR SEMICONDUCTOR TEST

(76) Inventor: Kwang-Suk Song, Seongnam-City (KR)

Correspondence Address: IPLA P.A., 3580 WILSHIRE BLVD., 17TH FLOOR, LOS ANGELES, CA, 90010, US

(21) Appl. No.: 12/281,478

(22) PCT Filed: Dec. 22, 2006
(86) PCT No.: PCT/KR2006/005646

§ 371 Date: Sep. 2, 2008

(30) Foreign Application Priority Data
Dec. 26, 2005 (KR) 20-2005-0036327
Dec. 22, 2006 (KR) PCT/KR2006/005646

(51) Int. Cl. G01R 31/26

(52) U.S. Cl. 324/754

(57) ABSTRACT

A probe card for testing semiconductor devices is disclosed, which can precisely test semi-conductor chips, in which probes, probe bars, and a probe block housing of the probe card are improved, such that the durability of each part of the probe card is increased. The probe card comprises: a probe for absorbing and dispersing elasticity; a probe bar for receiving the probe and preventing the probe from bending; and a probe block housing for mounting probe blocks connected in parallel with each other. Each probe block is formed as the probe bars are assembled thereto.

### TECHNICAL FIELD

The present invention relates to techniques for testing semiconductor devices, and more particularly to a probe card for testing semiconductor devices that can precisely test semiconductor chips, in which probes, probe bars, and a probe block housing of the probe card are improved, such that the durability of each part of the probe card is increased.

### BACKGROUND ART

The conventional blade probe made of Be—Cu metal thin plate has disadvantages in that its hardness, elasticity, wear-resistance, heat-resistance, etc. are not satisfactory characteristics for a probe. Since the conventional blade probe is fabricated by a wet etching manner with use of chemicals, it also cannot etch a thin plate consistently and accurately, and its needle part becomes rapidly worn out and oxidized. Furthermore, when a chip is tested by the probe, a large amount of aluminum particles, etc. adheres to the probe, in which the aluminum particles are generated as the needle part scrubs the chip.

When a large amount of particles adheres to the probe, contact resistance increases, such that the chip test cannot be performed normally. Therefore, the probe in such a state cannot perform a chip test.

When a probe is fabricated by chemically etching a metal thin plate, most of needle parts of the probe are formed as a rectangle shape. The needle part of a rectangular shape has a large surface area, causing a scrub mark to be unsteady. Therefore, scrubbing of the needle part cannot be uncontrolled either. Ideally, the needle part of the lower contact unit of the probe should be formed in such a way that its shape is circular, its size is less than 10 μm, and its end part is semi-round.

On the other hand, a conventional vertical probe card of a ceramic-bar type needs 2˜3 ceramic bars to fix one probe that tests one D-RAM chip, in a state where pads are aligned in LOC or DLOC (which is a alignment manner where pads are aligned at the center of the D-RAM chip). Also, the vertical probe card needs 3˜4 ceramic bars to fix one probe that tests one land flash memory chip, in a state where pads are aligned at both sides of the chip (which is called a “Perimeter” structure).

That is, the conventional vertical probe card must secure a space equivalent to the size of one semiconductor chip, depending on the type of semiconductor chip. The secured space is an area into which 2˜3 ceramic bars or 3˜4 ceramic bars together with two probes are inserted.

Also, a conventional ceramic probe bar inserts a probe into one or two slit grooves formed at one side or both sides thereof and then fixes them thereto using an epoxy. However, since ceramic materials are strong, the depth and width for a slit groove are formed differently when grooving, deviating from an initial set value. Most often, such a deviation is largely shown in the middle part of the slit groove. That is, as such a grooving is performed, accumulation tolerance for the slit groove increases. As a result, the dimensions of the last formed slit groove are quite different from those of the first formed slit groove.

In addition, due to such a strong ceramic characteristic, a circular blade excavating slit grooves is rapidly abraded and thus takes a relatively long time to machine one probe bar, thereby decreasing productivity and cost-efficiency.

A conventional probe bar for plural chips is fabricated in such a way that a probe greater than 100 mm is machined and then fixed to the probe bar by with an epoxy and adhesive. However, stress from the epoxy and adhesive makes the middle portion of the probe bar bend by approximately 30 μm.

Such a bend causes a problem that the probe and pads of the chip do not meet each other. Therefore, the probe does not scrub the pads and thus the probe card cannot test the chip.

Also, the conventional probe block housing is configured in such a way that its inside is formed in a rectangular shape and its size is greater than the size of a wafer so that it may test a wafer of 8 or 12 inches, one at a time. The wafer is formed in such a way that the top and bottom parts of the beginning and ending regions of the pattern-formed chips do not have pattern-formed chips. That is, since the wafer is circular, and the probe block housing is rectangular, useless space is generated at the corners of the probe block housing, which causes the probe bars to be elongated.

More specifically, since the wafer is circular and the inside of the probe block housing is rectangular, the inside corners of the probe block housing is useless space. The inside corners are useless because the circular wafer does not have pattern-formed chips at the corresponding inside corners. Therefore, lengthwise-beginning columns 1˜4 cannot be tested, and opposing-lengthwise columns 1˜4 cannot be tested, either.

In order to resolve this problem of useless areas, the probe block housing is modified to have an octagon structure similar to a circular wafer. That is, the octagonal probe block housing is formed in such as way that the length of a probe bar is the same as that of the internal octagon structure.

Also, another conventional probe card is configured in such a way that a test head is formed as a plate-space transformer, and a probe attached to the test head is mostly made of a ceramic plate.

The conventional probe card requires a ceramic plate greater than 8 inches for an 8-inch wafer, and a ceramic plate greater than 12 inches for a 12-inch wafer.

When a ceramic plate of 8 inches is tested under a high temperature condition, thermal expansion occurs in the length and width directions of 35 μm, respectively. The greater the ceramic plate size, the more the thermal expansion increases, thereby increasing the area of the ceramic plate.

When the ceramic plate to which probes are attached is expanded during a test under a high temperature condition, probe needles of the probe cannot completely scrub pads of a chip. Therefore, the probe card in such a state cannot perform a chip test.

Generally, the probe card is fabricated to have a chip pad pitch under a temperature of 25° C. However, a wafer is tested under a room temperature condition of 25° C. at its first test step, under a high temperature condition of 85˜100° C. at its second test step, and under a low temperature condition at its third test step.

However, when the wafer test is performed under such a high temperature condition, the pads of the wafer, such as a silicon wafer, are dislocated due to thermal expansion.

That is, since the silicon wafer and the probe card are made of different materials, and thus have different thermal expansion coefficients, such a thermal expansion result has led to missing the positions between the chip pads of the silicon wafer and the probe needles of the probe card. Therefore, the probe card made of different material from the wafer cannot completely test the wafer.

Also, wafer burn-in test and wafer level burn-in test test a wafer at 120° C. and cause a serious thermal expansion problem.

### DISCLOSURE OF INVENTION

### Technical Problem

Therefore, the present invention has been made in view of the above problems, and it is an object of the present invention to provide a probe card for testing semi-conductor devices configured to have a structure where it can test the all pattern-formed chips on one wafer with a one-time scrubbing manner, in which the size of the probe housing increases according to a the number of probes used.

It is another object of the present invention to provide a probe card for testing semi-conductor devices that can test the all patterned-formed chips on one wafer, such as 8 inches, and 12 inches, with a one-time scrubbing manner, without damage of the wafer caused by a probe pressure of a few hundred of kilograms, which may be generated by 3 g per probe while the probes scrubs the chip pad, in which the probe card has tens of probes attached thereto.

Yet another object of the present invention is to provide a probe card for testing semiconductor devices that can restrain the bend of a probe bar that occurs as the probe bar increases in length, and can minimize the thermal expansion generated when a wafer is tested under a high temperature condition.

### Technical Solution

In accordance with the present invention, the above and other objects can be accomplished by the provision of a probe card for testing semiconductor devices comprising: a probe for absorbing and dispersing elasticity; a probe bar for receiving the probe and preventing the probe from bending; and a probe block housing for mounting probe blocks connected in parallel with each other. Each probe block is formed as the probe bars are assembled thereto.

Preferably, the probe comprises a lower end contact unit. The lower end contact unit includes: a flexible supporting unit shaped as a spring, having a structure of a single or double stage; an elastic absorption unit for absorbing elasticity, having a cross-section of “ [symbol] ”; and a needle shaped as a semi-round.

Preferably, the probe forms a plurality of holes in a body thereof, the holes discharging heat generated when performing a test at a high temperature condition.

Preferably, the probe is configured in such a way that the flexible supporting unit shaped as a spring, having a structure of single or double stage, is cut at a portion connected to an arm of the lower end contact unit to form a spaced part. The arm is restrictedly moved within the space part when the probe scrubs the pad.

Preferably, the lower end contact unit of the probe is formed in such a way that spring-like structures are symmetrically aligned and a needle is located at the center thereof.

Preferably, the lower end contact unit is symmetrically shaped, and the spring positioned at the opposite side of the needle whose arm has a cantilever structure is thicker than that of the spring of the needle.

Preferably, an upper end contact unit of the probe has a settlement groove for a joining surface by the width of the PCB pad, in which the settlement groove forms a plurality of protrusions shape as saw-teeth and the arm has a structure of a double stage.

Preferably, the probe is shaped as a desired form by a selected metal through a sputtering process or a plating process and a CMP process, in which the position of the needle direction of the lower end contact unit and the position of the direction of the upper contact unit are determined according to alignment of semiconductor pad.

Preferably, the probe forms a basic conduction layer by Ni or Ni alloy, and a plating layer by plural metals selected form Mn, Mo, Cu, Au, W, Rh, Co, or Cr.

Preferably, the probe bar forms protruding units equivalently spaced apart from each other at its one side or both sides, in which the bottom surface between the protruding units is coated with epoxy to form an epoxy layer of uniform thickness. The epoxy layer has a plurality of slit grooves whose positions are the same as those as the semiconductor pads.

Preferably, the probe bar is made of one of a ceramic plate, silicon carbide plate, silicon plate, quarts glass plate, or semiconductor epoxy resin plate.

Preferably, the probe block housing is made of ceramic. Also, the probe block housing is configured in such a way that its inside and outside are shaped as an octagonal plate shape, the edge of its outside is formed as a step, and the inside has a step structure such that the probe block can be installed on the step surface.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a front view illustrating a probe of a probe card for testing semiconductor devices according to the present invention;

FIGS. 2 to 6 are front views illustrating one end of other embodiments of the probe of the probe card according to the present invention;

FIG. 7 is a perspective view illustrating a probe bar of the probe card according to the present invention;

FIG. 8 is a top view illustrating a state where probes are inserted and fixed to the probe bars, according to the present invention; and

FIG. 9 is a top view illustrating a state where probe bars with probes are mounted to the probe block housing, according to the present invention.

### MODE FOR THE INVENTION

Preferred embodiments according to a probe card for testing semiconductor devices of the present invention will be described in detail with reference to the accompanying drawings.

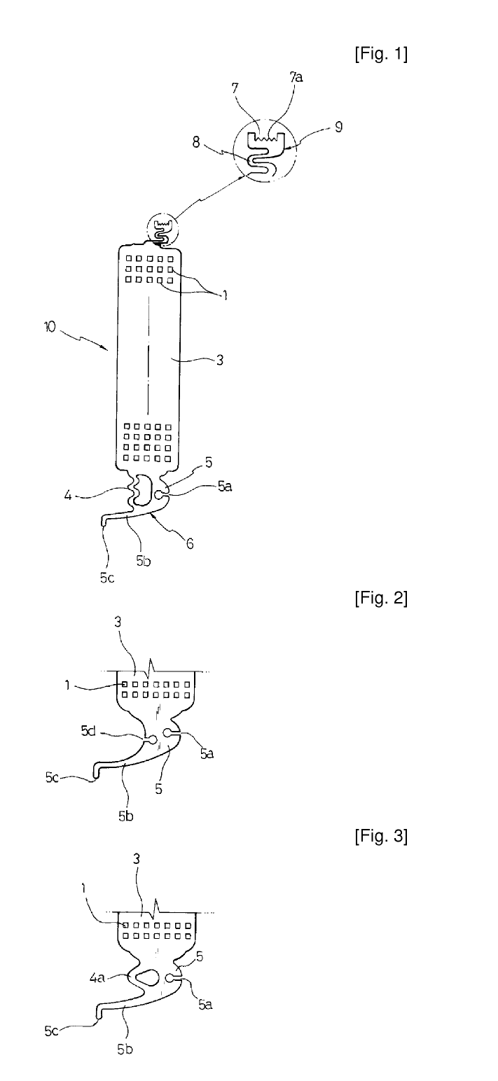

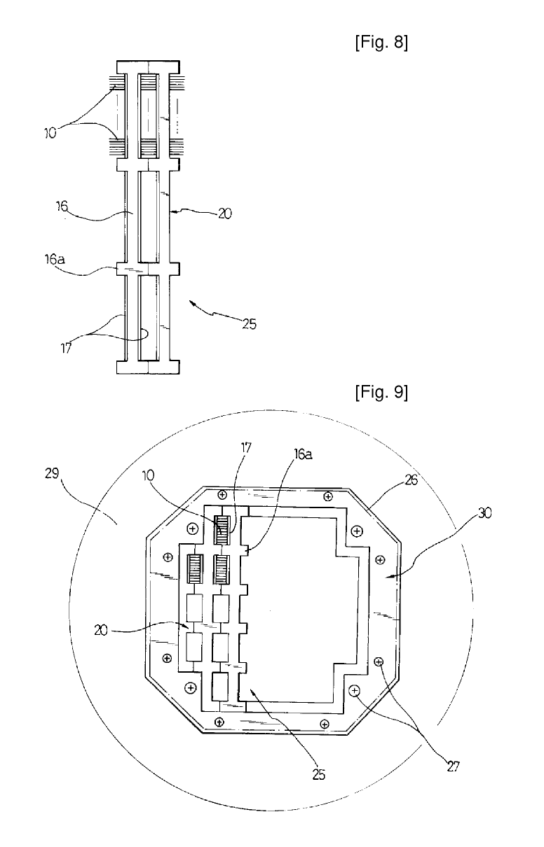

FIG. 1 is a front view illustrating a probe of a probe card for testing semiconductor devices according to the present invention. FIGS. 2 to 6 are front views illustrating one ends of other embodiments of the probe of the probe card according to the present invention. FIG. 7 is a perspective view illustrating a probe bar of the probe card according to the present invention. FIG. 8 is a top view illustrating a state where probes are inserted and fixed to the probe bars, according to the present invention. FIG. 9 is a top view illustrating a state where probe bars with probes are mounted to the probe block housing, according to the present invention.

As shown in FIGS. 1, 7, 8, and 9, the probe card, according to the present invention, includes probes 10, probe bars 20 receiving the probes 10, and a probe block housing 30 to which the probe bars 20 are fixedly mounted.

The probe 10 is fabricated as a desired structure in such a way that an ideal metal to test a wafer is carefully selected, and then processed by plating or sputtering to form three layers. For example, the metal preferably has the characteristics of superior hardness, elasticity, wear-resistance, heat-resistance, conductivity, etc.

Here, the first metal layer is preferably formed by a Ni alloy, the second layer is preferably formed by a metal having high conductivity, and the third layer is preferably formed by a metal having good wear-resistance, hardness, and elasticity. On the other hand, the material for the first metal layer is not limited to the Ni alloy. Similarly, the materials for the second and third metal layers can be selected from others, depending on sputtering or plating methods.

The probe 10 of the present invention can be fabricated as a certain shape, forming a basic conduction layer by Ni or Ni alloy, and a plating layer by plural metals selected from Mn, Mo, Cu, Au, W, Rh, Co, or Cr.

Also, the probe 10 is fabricated as a fine and uniform shape through a photolithography process, an etching process, sputtering or metal plating process, and a chemical mechanical polishing (CMP) process, which are a part of semiconductor processes.

The structure of the probe 10 and its modified structures are formed as shown in FIGS. 1, and 2 to 6. That is, the lower part of a body 3 integrally forms with a lower end contact unit 6 and the upper part of the body 3 integrally forms with an upper end contact unit 9.

The body 3 of the probe 10 forms a plurality of holes 1 such that heat can be discharged outside, which is generated as a wafer test is performed for a relatively long time in a condition that current flows through the probe bar under a high temperature. On the other hand, the probe bar 20 is installed adjacent to other probe bars in such as way that the holes of one probe bar are facing those of others, the probe bars having a space therebetween function as a capacity of capacitance.

Also, the lower end contact unit 6 is shaped in such a way to prevent separation of the probe 10 from the chip pad when the probe 10 scrubs the chip pad, thereby enabling the probe 10 to perform a precise test.

A vertical metal cantilever blade probe with a lengthy arm may be deviated from the center of a chip pad while the probe is scrubbing the chip pad. When the probe is deviated from the chip pad, the probe is slipped and then separated from the chip pad.

Also, when the inserted probes 10 are not uniform in such a way that their ends have irregular heights (, or a flatness of a big difference), the probes 10 scrub, in a slanting state, the chip pad, and thus are separated from the chip pad in the over drive. Therefore, the normal chip may be determined to be ineffectual by such a poor scrubbing.

The structure of the lower end contact unit 6 is configured to include: a flexible supporting unit 4; an elastic absorption unit 5 having a cutting part 5a for absorbing elasticity, which is formed as a curve part of the elastic absorption unit 5 is cut at its center part; and a needle 5c formed at the outside end of the arm 5b. Therefore, from such a structure, the lower end contact unit 6 prevents the probe 10 from separating and scrubbing.

The flexible supporting unit 4, shaped as a spring, prevents separation of the probe 10 from the chip pad by the needle 5c as it applies its elasticity thereto. Also, the flexible supporting unit 4 prevents damage of the chip pad.

In addition, the cutting part 5a of the elastic absorption unit 5 is formed at the rear side of the flexible supporting unit 4. The cross-section of the cutting part 5a is shaped as “ [symbol] ”. Such a structure serves to absorb pressure generated by elasticity generated when the needle 5c scrubs the chip pad and, at the same time, disperses the pressure to allow scrubbing.

In addition, the surface of the end portion of the needle 5c is shaped as a curve, or a semi-round structure, to achieve a uniform scrub mark generated as the needle scrubs the chip pad, thereby allowing the probe to perform a precise test.

The direction of the needle 5c and the direction of the lower end contact unit are determined according to the position of pad alignment of the semiconductor devices.

On the other hand, the probe 10 of FIG. 1 can be modified or changed into embodiments as shown in FIGS. 2 to 6, but their test effects are the same as that of the probe 10 of FIG. 1.

That is, FIG. 2 shows an elastic absorption unit (5, 5a, and 5d) of a lower end contact unit, in which 5a and 5d are cut out as a shape“ [symbol] ”.

FIG. 3 shows a flexible supporting unit 4a having one curving unit.

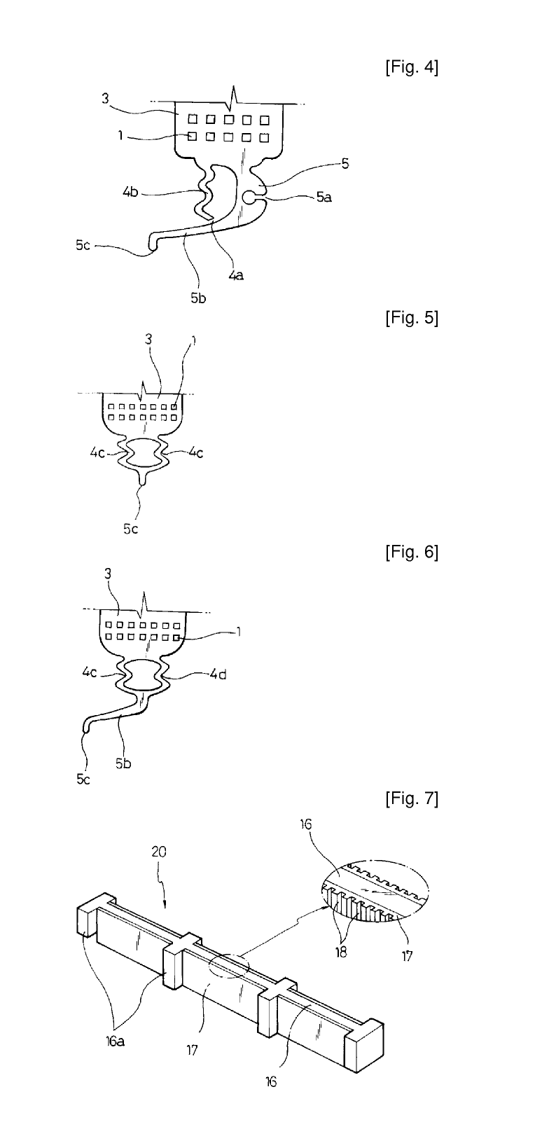

As shown in FIG. 4, the probe is configured in such a way that the flexible supporting unit 4b, shaped as a spring, is cut to be separated from the arm 5b forming a spaced part 4a, within which the arm 5b is moved restrictedly when the probe 10 scrubs the pad.

As shown in FIG. 5, the lower end contact unit is configured in such a way that spring-like elastic absorption units 4c are symmetrically aligned at both sides thereof and a needle 5c is positioned at the center thereof.

As shown in FIG. 6, the lower end contact unit can be modified from that of FIG. 5 in such a way that the arm 5b is extended to the outside long. Here, the spring-like absorption unit 4c is thicker than that of the spring-like absorption unit 4d.

On the other hand, the upper end contact unit 9 is fixedly mounted to the upper part of the body 3 as it is connected and then joined at a time. The arm 8 of the upper end contact unit 9 is shaped to have two spring stage structures (first and second spring stages) such that a spring unit can absorb elasticity generated when the first and second spring stages are mounted to be fixed. The first spring stage adjusts joining elasticity. The second spring stage adjusts tightening elasticity when adjusting the flatness of the probe.

In order to prevent the joining side of the PCB from escaping from a chip pad located on the flat lower side by vibration generated when the probe card is operated at a probe station, the upper contact unit 9 is configured to have the following structure:

That is, in order to separate the joining side from a chip pad, a settlement groove 7 shaped as “ [symbol] ”is formed by the width of the pad land. The settlement groove 7 has a plurality of protrusions 7a and is integrally formed with the body 3 by the spring-like arm 8.

Also, when the probe card is used under a high temperature condition, the position of the probe 10 is changed. That is, when the wafer and probe card, which are made of different materials, are under the high temperature condition, the wafer chip pad and the probe of the probe card do not precisely meet each other. Therefore, such a result causes the reliability of the test to deteriorate.

The wafer test is tested under a room temperature condition of 25° C. at its first test, under a high temperature condition of 85˜100° C. at its second test step, and under a low temperature condition at its third test step.

However, when the wafer test is performed under such a high temperature condition, the pad position of the chip is changed by thermal expansion of the silicon wafer.

Also, wafer burn-in test and wafer level burn-in test test a wafer at 120° C. and cause a serious thermal expansion problem.

Such a result is caused because thermal expansion coefficients of the wafer material and the probe card material are different from each other.

In order to resolve the problems regarding the thermal expansion, the probe card of the present invention is configured in such a way to make the probe bars 20 form a lengthwise group, instead of the use of a test head fabricated by a single plate. Such a structure of the present invention can reduce changes of position between the probe card and the chip pad.

Thermal expansion in the width of the probe block 25 does not cause a problem while performing a chip test, but lengthwise thermal expansion may cause a problem. Therefore, it is important to reduce the lengthwise thermal expansion of the probe block.

When the number of the groups of lengthwise aligned probe bars 10 is greater than a certain number of devices under test (DUT), the probe blocks 25 can be configured in such a way that they are independently classified and then successively connected one another.

The conventional ceramic bar for testing plural chips is configured in such a way that a probe bar, which is 1.5˜2.1 mm in thickness and 100 mm in length, is machined and probes are fixed to the probe bar by an epoxy and adhesive. Here, the probe bar may be curved in such a way that its middle portion is protruded by approximately 30 μm from the normal state due to stress of the epoxy and adhesive.

When the probe bar is curved, the probe does not meet with the chip pad and thus cannot scrub the chip pad. Therefore, the curved probe bar becomes useless for a chip test.

In order to prevent such a curving of the probe bar, the probe bar 20 of the present invention is configured in such a way that its total length is divided in equal parts based on a certain distance, and its one side or both sides form protruding units 16a of approximately 2 mm at their boundaries. The bottoms of the probe bar between the protruding unit 16a form an epoxy layer 17 uniformly coated by epoxy at a constant thickness.

The epoxy layer 17 forms a plurality of slit grooves 18 such that the probes 10 can be vertically inserted and fixed thereto, and forms a gap between adjacent two slit grooves to correspond to a pitch of the semiconductor chip pad.

Therefore, when such probe bars 20 whose one side or both sides have protruding units 16a are joined together to form a probe block 25, the probe blocks 25 are not curved. After that, the probe block 25 is in plural mounted on the probe block housing 30, in parallel.

Here, the number of the protruding unit 16a is determined based on the number of DUT and intervals of a chip pad. Each protruding unit 16a is determined in size according to the pitch of the chip pad.

In order to prevent a curving of the probe bar 20, the probe bars each form protruding 16a at both of their ends and sides with the equivalent distance, and then the probe bars are joined in such as way that the protruding units of one probe bar are correspondingly joined with those of the adjacent probe bar. After that, the adjoined probe bars are mounted on the probe block housing 30, in parallel.

The probes 10 are fixed to the probe bar 20 in such a way that they are inserted to the slit grooves 10 formed on the epoxy layer 17 between the protruding units 16a and then adhered by adhesive.

The probe bar 20 is not limited to a well-known ceramic, instead may be formed by one of a silicon carbide plate, silicon plate, quarts glass plate, or semiconductor epoxy resin plate.

Also, the probe block housing 30 of the present invention is configured in such a way that its inside is shaped to be rectangular or octagonal from a plate to test a wafer of 8 inches or 12 inches at a time. On the other hand, although the top and bottom portions of the beginning region and the opposing regions of a wafer do not have pattern-formed chips, the probe bar 20 should cover the regions. Therefore, the probe bar 20 uselessly elongates and thus the probe block housing 30 should secure the useless space, which causes the probe card to be large.

The rectangular probe block housing 30 is larger than the wafer size, and thus its corner regions are useless. Therefore, the probe bar 20 must not be long.

In order to resolve the problem, the probe bar 20 is configured in such a way that its inside is formed as an octagonal shape with steps. Such a probe bar 20 is joined with an adjacent probe bar in parallel and then mounted on the probe block housing 30.

Also, the outer edge of the probe block housing 30 of octagon is shaped as a step. The step part 26 is supported by a lower reinforcing plate and then integrally coupled to the PCB by screw bolts 27.

Recently, a wafer test is performed in such a way to test the all chips formed on a wafer of 8 or 12 inches by a one time scrubbing manner.

To this end, the probe block housing must be the same size as the wafer.

According to the types of semiconductor devices, a probe block is firstly fabricated to have a space to which 2˜3 probe bars or 3˜4 probe bars together with two probes can be inserted. Here, the space secures the same area as a chip. After that, the probe blocks are grouped lengthwise by a necessary number of DUT, and then connected to each other in parallel, thereby testing plural chips.

The number of probe bars, the size of the probe blocks, and the size of the probe block housing are determined according to the chip size and the number of scrub motion used in a test.

The probe card as described above tests all chips patterned on a wafer in such a way to allow the test head to scrub the all chips at a time, and then determines as to whether the chips are good or bad.

### INDUSTRIAL APPLICABILITY

As described above, the probe card for testing semiconductor devices according to the present invention can be configured in such a way that the joining part for the probe is shaped to correspond to the types of semiconductor devices, test a semi-conductor chip patterned wafer of 8 or 12 inches at a time, disperse and absorb scrubbing weight of tens of probes when performing the wafer test, and prevent a bend phenomenon of the probe bar caused as a probe and probe bar increases in length, in which the probe and probe bar are shaped in such a way that the probe cannot be deviated from the chip pad.

Also, the probe card, according to the present invention, has better characteristics than the conventional thin plate probe, such as its hardness, elasticity, wear-resistance, and heat-resistance, etc. In addition, the probe card of the present invention improves the electrical and physical performance of the conventional probe as metal sufficiently satisfying the demanded conditions for a probe is selected and then processed by a sputtering process, or a plating process, and a CMP process.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. (canceled)

2. A probe card for testing semiconductor devices including: a probe for absorbing and dispersing elasticity caused by adding a lower end contact unit to a lower unit of a body forming a plurality of holes and by adding a upper end contact unit to a upper portion of the body; a probe bar for receiving the probe one side or both sides thereof; and a probe block housing for mounting probe blocks connected in parallel with each other, in which each probe block is formed as the probe bars are assembled thereto, wherein the probe comprises the lower end contact unit, the lower end contact unit comprising:
a flexible supporting unit shaped as a spring, having a structure of a single or double stage;
an elastic absorption unit for absorbing elasticity, having a cross-section of [symbol] ; and
a needle shaped as a semi-round.

3. The probe card according to claim 2, wherein the probe forms a plurality of holes in a body thereof, the holes discharging heat generated when performing a test at a high temperature condition.

4. The probe card according to claim 2, wherein the probe is configured in such a way that the flexible supporting unit shaped as a spring, having a structure of single or double stage, is cut at a portion connected to an arm of the lower end contact unit to form a spaced part, in which the arm is restrictedly moved within the space part when the probe scrubs the pad.

5. The probe card according to claim 2, wherein the lower end contact unit of the probe is formed in such a way that spring-like structures are symmetrically aligned and a needle is located at the center thereof.

6. The probe card according to claim 5, wherein the lower end contact unit is symmetrically shaped, and the spring positioned at the opposite side of the needle whose arm has a cantilever structure is thicker than that of the spring of the needle.

7. The probe card according to claim 2, wherein an upper end contact unit of the probe has a settlement groove for a joining surface by the width of the PCB pad, in which the settlement groove forms a plurality of protrusions shape as saw-teeth and the arm has a structure of a double stage.

8. The probe card according to claim 2, wherein the probe is shaped as a desired form by a selected metal through a sputtering process or a plating process and a CMP process, in which the position of the needle direction of the lower end contact unit and the position of the direction of the upper contact unit are determined according to alignment of semiconductor pad.

9. The probe card according to claim 2, wherein the probe forms a basic conduction layer by Ni or Ni alloy, and a plating layer by plural metals selected form Mn, Mo, Cu, Au, W, Rh, Co, or Cr.

10. The probe card according to claim 2, wherein the probe bar forms protruding units equivalently spaced apart from each other, along the side forming a plurality of slit grooves, in which the protruding units prevent the probe bar from bending.

11. (canceled)

12. The probe card according to claim 2, wherein:
the probe block housing is made of ceramic;
the probe block housing is configured in such a way that its inside and outside are shaped as an octagonal plate shape, the edge of its outside is formed as a step, and the inside has a stop structure such that the probe block can be installed on the step surface.
